(19) United States
(12) Patent Application Publication
(10) Pub. No.: US 2012/0166905 A1
(43) Pub. Date: Jun. 28, 2012

(54) METHOD AND APPARATUS FOR CONTROLLING DECODING IN RECEIVER

(75) Inventors: Se-Ho MYUNG, Suwon-si (KR); Hyun-Koo Yang, Seoul (KR); Hong-Sil Jeong, Seoul (KR)

(73) Assignee: Samsung Electronics Co., Ltd., Suwon-si (KR)

(21) Appl. No.: 13/335,081

(22) Filed: Dec. 22, 2011

(30) Foreign Application Priority Data
Dec. 24, 2010 (KR) 10-2010-0134459

(51) Int. Cl. H03M 13/09; G06F 11/10; H03M 13/05

(52) U.S. Cl. 714/752; 714/799; 714/E11.032

(57) ABSTRACT

Methods and apparatus are provided for controlling decoding in a receiver. A codeword is received and decoded. It is determined whether the decoding is a decoding success or a decoding failure. A number of unreliable bits of the codeword is determined when the decoding is the decoding failure. Iterative decoding is performed when the number of unreliable bits is less than a first threshold value.

### PRIORITY

This application claims priority under 35 U.S.C. §119(a) to an application filed in the Korean Intellectual Property Office on Dec. 24, 2010 and assigned Serial No. 10-2010-0134459, the contents of which are incorporated herein by reference.

### BACKGROUND OF THE INVENTION

1. Field of the Invention

The present invention relates generally to a receiver of a broadcasting system, and more particularly, to a method and apparatus for controlling decoding in a receiver.

2. Description of the Related Art

Powerful error correction encoding techniques that support broadband data and fast packet transmission are integral for next-generation communication and broadcasting systems. Since the introduction of a turbo coding scheme in 1993, there has been an increased interest in high-performance error correction codes that provide an error probability that approaches the Shannon limit. The IMT-2000 system also uses a turbo code. The core technology of a turbo code is an iterative decoding technique, which has evolved into new fields. However, the turbo code is limited in performing at a considerably low error probability, which is required in next-generation communication/broadcasting systems. Thus, there has been an increasing interest in new graph-based encoding schemes. Accordingly, a Low Density Parity Check (LDPC) code has been utilized as an error correction code.

The LDPC code performs in a manner that approaches the Shannon limit when a belief propagation-based iterative decoding algorithm is used. In general, the LDPC code determines decoding termination by syndrome-check (H×c=0). Herein, ‘H’ denotes a parity check matrix, and ‘c’ denotes a codeword.

The syndrome-check is typically not passed in a region where a Signal-to-Noise Ratio (SNR) is low or an error occurs frequently. Therefore, decoding is performed as many times as the maximum decoding iteration count set in the system.

However, this may increase a decoding failure probability and may cause a decoding inefficiency. Specifically, the decoding iterations may cause power consumption and latency.

### SUMMARY OF THE INVENTION

The present invention has been made to address at least the above problems and/or disadvantages and to provide at least the advantages below. Accordingly, an aspect of the present invention relates to a method and apparatus for controlling decoding in a receiver.

Another aspect of the present invention relates to a decoding method and apparatus for controlling a decoding iteration count by determining whether decoding will fail, even when performed in a low-SNR region as many times as the maximum decoding iteration count.

According to an aspect of the present invention, a method for controlling decoding in a receiver is provided. A codeword is received and decoded. It is determined with the decoding is a decoding success or a decoding failure. A number of unreliable bits of the codeword is determined when the decoding is the decoding failure. Iterative decoding is performed when the number of unreliable bits is less than a first threshold value.

According to another aspect of the present invention, a receiver is provided that includes a decoding unit for decoding a received codeword. The receiver also includes a control unit for determining whether the decoding is a decoding success or a decoding failure. A number of unreliable bits of the codeword is determined when the decoding is the decoding failure. Iterative decoding is performed when the number of unreliable bits is less than a first threshold value.

According to a further aspect of the present invention, a method for controlling decoding in a receiver is provided. A codeword is decoded. A number of unreliable bits of the codeword is determined when the decoding is a decoding failure. An average variation of the number of unreliable bits is determined. A number of times when the average variation of the number of unreliable bits decreases below a first threshold value during iterative decoding is determined. The iterative decoding is terminated when the determined number of times reaches a second threshold value.

### BRIEF DESCRIPTION OF THE DRAWINGS

The above and other aspects, features, and advantages of the present invention will be more apparent from the following detailed description when taken in conjunction with the accompanying drawings in which:

FIG. 1 is a graph illustrating the ratio of bits having an absolute Log Likelihood Ratio (LLR) value less than a specific value T to LDPC-encoded bits according to a decoding iteration count, in the event of a decoding failure;

FIG. 2 is a graph illustrating the ratio of bits having an absolute LLR value less than a specific value T to LDPC-encoded bits according to a decoding iteration count, in the event of a decoding success;

FIG. 3 is a flow chart illustrating a process for controlling LDPC decoding in a receiver, according to an embodiment of the present invention; and

FIG. 4 is a block diagram of an apparatus for controlling LDPC decoding in a receiver, according to an embodiment of the present invention.

### DETAILED DESCRIPTION OF EMBODIMENTS OF THE PRESENT INVENTION

Embodiments of the present invention are described in detail with reference to the accompanying drawings. The same or similar components may be designated by the same or similar reference numerals although they are illustrated in different drawings. Detailed descriptions of constructions or processes known in the art may be omitted to avoid obscuring the subject matter of the present invention.

Embodiments of the present invention provide a method and apparatus for controlling decoding in a receiver.

The following description is made in the context of a receiver employing an LDPC code that is a linear block code capable of iterative decoding. Embodiments of the present invention are not limited to these codes. Thus, it should be understood that the present invention may also be applicable to any other receivers employing iterative decoding.

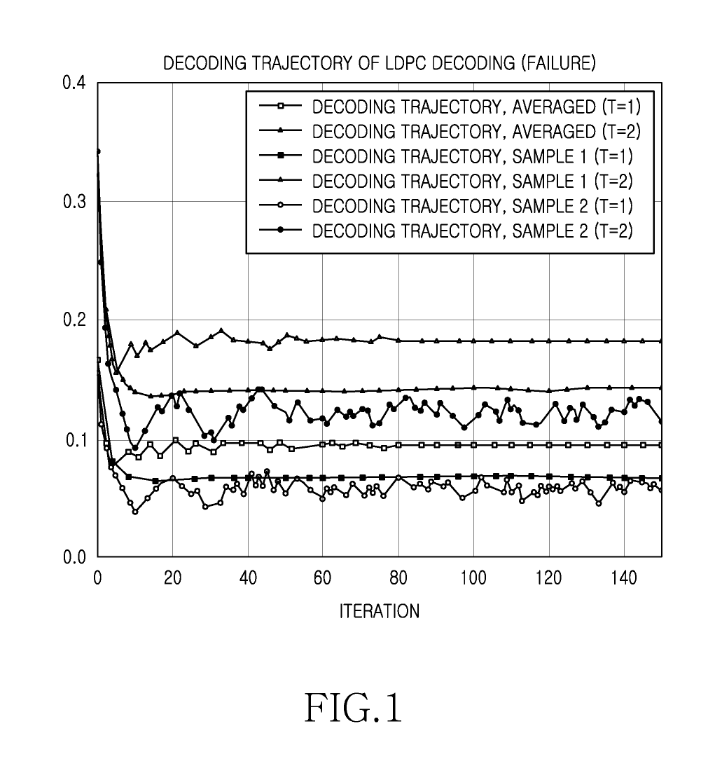

FIG. 1 is a graph illustrating the ratio of bits having an absolute LLR value less than a specific value T to LDPC-encoded bits according to a decoding iteration count, in the event of a decoding failure, in the case of an Additive White Gaussian Noise (AWGN) channel.

Referring to FIG. 1, an X-axis represents a decoding iteration count, and a Y-axis represents the ratio of bits having an absolute LLR value that is obtainable in a decoding process and that is less than a specific value T, to all the bits constituting an LDPC codeword. Specifically, FIG. 1 illustrates the ratio of bits having an absolute LLR value that is obtainable in a decoding process and that is less than 1 or 2, to LDPC codeword bits. “Decoding Trajectory, Averaged” represents an average value of the ratio of bits having an absolute LLR value less than a specific value T to bits of a plurality of LDPC codewords (e.g., 1000). “Decoding Trajectory, Sample 1” and “Decoding Trajectory, Sample 2” represent a change in the ratio of each of the codewords selected from the plurality of LDPC codewords (e.g., 1000). In general, the ratio of bits having an absolute LLR value less than a specific value T decreases as the decoding iteration count increases. This relationship occurs because the number of unreliable bits in an LDPC codeword decreases as the decoding iteration count increases.

However, in the event of a decoding failure, the ratio of bits having an absolute LLR value less than a specific value T does not decrease. Specifically, the ratio of bits having an absolute LLR value less than a specific value T does not decrease because there is a limitation in correcting all of the unreliable bits. This limitation even occurs when decoding is performed in a low-SNR environment a number of times equal to the maximum decoding iteration count. Referring to FIG. 1, the ratio of bits having an absolute LLR value less than a specific value T does not decrease on the average in the event of a decoding failure, as represented by “Decoding Trajectory, Averaged”.

The simulation result of FIG. 1 reveals that a fluctuation occurs according to an error pattern in the event of a decoding failure. Referring to FIG. 1, a slight fluctuation may occur in the process of iterative decoding, but the ratio of bits having an absolute LLR value less than a specific value T tends to converge stably after completion of sufficient iterative decoding, as represented by “Decoding Trajectory, Sample 1”. However, it is also observed that a considerable fluctuation occurs as represented by “Decoding Trajectory, Sample 2”.

The fluctuation of “Decoding Trajectory, Sample 2” occurs because belief propagation-based iterative decoding is performed for an LDPC codeword. Theoretically, if the length of an LDPC codeword is infinite, the absolution LLR value increases because each of the LDPC-encoded bits receives independent information, capable of increasing belief continuously according to iterative decoding, from the bits, except the LDPC-encoded bits. Practically, because the length of an LDPC codeword is finite, dependent information is received by the interaction between LDPC-encoded bits, and thus, belief does not propagate. If the interaction between erroneous LDPC-encoded bits is not strong, only a small fluctuation occurs as represented by “Decoding Trajectory, Sample 1”. If the interaction between erroneous LDPC-encoded bits is strong, a large fluctuation may occur as represented by “Decoding Trajectory, Sample 2”.

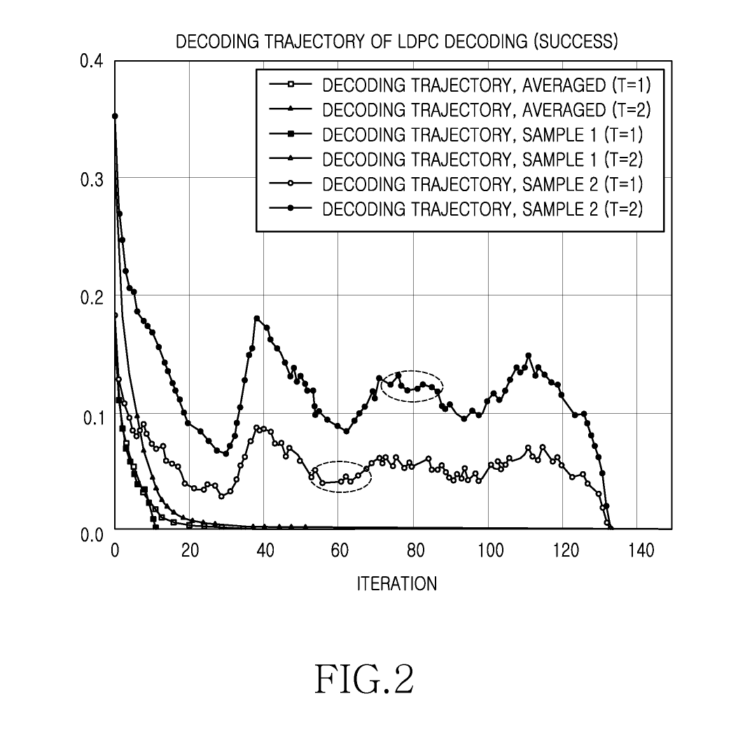

FIG. 2 is a graph illustrating the ratio of bits having an absolute LLR value less than a specific value T to LDPC-encoded bits according to a decoding iteration count, in the event of a decoding success, in the case of an AWGN channel.

Referring to FIG. 2, an X-axis represents a decoding iteration count, and a Y-axis represents the ratio of bits having an absolute LLR value that is obtainable in a decoding process and that is less than a specific value T, to all the bits constituting an LDPC codeword. In FIG. 2, “Decoding Trajectory, Averaged”, “Decoding Trajectory, Sample 1”, and “Decoding Trajectory, Sample 2” have the same meanings as those described above with respect to FIG. 1.

In general, the ratio of bits having an absolute LLR value less than a specific value T decreases as the decoding iteration count increases. This is relationship occurs because the number of unreliable bits in an LDPC codeword decreases as the decoding iteration count increases.

In the event of a decoding success, the ratio of bits having an absolute LLR value less than a specific value T decreases suddenly and approaches 0. In a high-SNR environment, all of the unreliable bits may be corrected as decoding is performed as many times as the maximum decoding iteration count. Therefore, the ratio of bits having an absolute LLR value less than a specific value T approaches 0.

Referring to FIG. 2, a fluctuation occurs according to an error pattern in the event of a decoding success. However, if the ratio is at or below a certain degree even once, a decoding success probability may increase with an increase in the decoding iteration count. As described with reference to FIG. 1, the fluctuation may occur according to an error pattern when belief-propagation decoding is applied to a finite-length LDPC code.

As represented by “Decoding Trajectory, Sample 2 (T=1)” in FIG. 2, the ratio of bits having an absolute LLR value less than a specific value T decreases to about 0.03 when iterative decoding is performed about 30 times. Thereafter, the ratio of bits having an absolute LLR value less than a specific value T increases suddenly above 0.08 when iterative decoding is performed about 40 times. However, if the ratio is at or below a certain degree even once, a decoding success probability may increase with an increase in the decoding iteration count. In the case of “Decoding Trajectory, Sample 2 (T=1)” in FIG. 2, decoding succeeds when the decoding iteration count is 133.

However, if a given system sets the maximum decoding iteration count to be less than 133, the decoding fails. If a given system sets the maximum decoding iteration count to be greater than 133, the decoding succeeds. Thus, it is possible to determine whether decoding will fail when the ratio reaches a suitable value even once, even if there is a variation in the ratio of bits having an absolute LLR value less than a specific value T. The suitable value may depend on the maximum decoding iteration count of a given system.

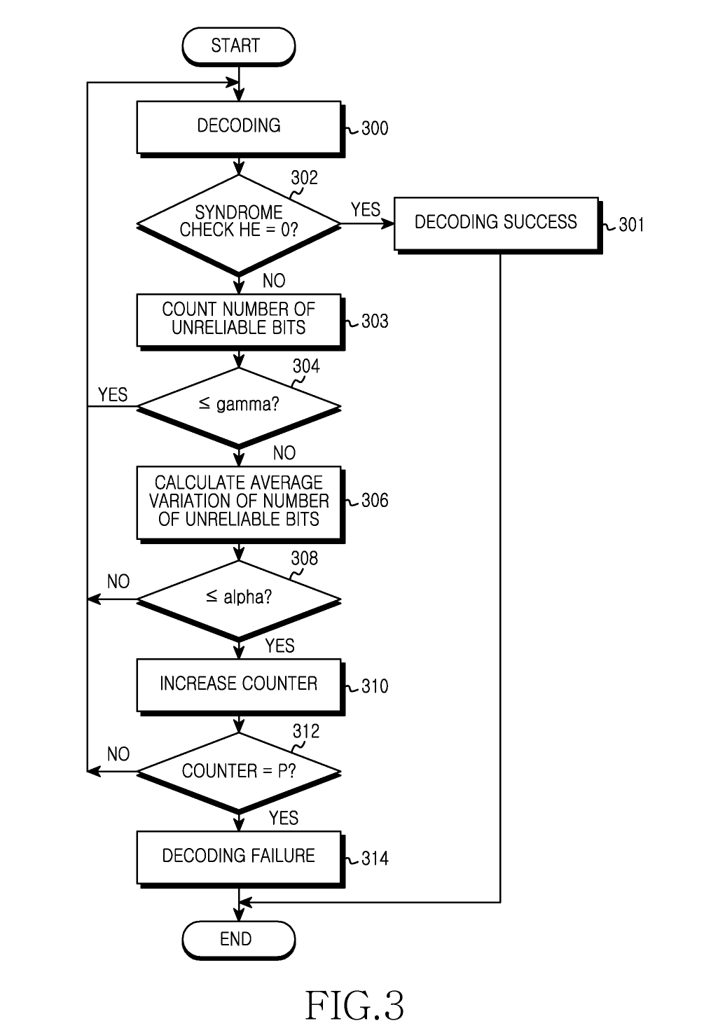

FIG. 3 illustrates a process for controlling LDPC decoding in a receiver according to an embodiment of the present invention.

Referring to FIG. 3, the receiver decodes an LDPC code in step 300.

In an embodiment of the present invention, an algorithm for decoding the LDPC code may be one of a message passing algorithm, a sum product algorithm, and a belief propagation algorithm.

In step 302, the receiver performs a syndrome check and determines whether an equation of H×c=0 is satisfied. ‘H’ denotes a parity check matrix and ‘c’ denotes a codeword. If the equation of H×c=0 is satisfied in step 302, the receiver determines a decoding success and ends the current LDPC decoding, in step 301. In another embodiment of the present invention, the receiver may start LDPC decoding of the next n information bits. If the equation of H×c=0 is not satisfied in step 302, the receiver proceeds to step 303 to perform iterative decoding.

In step 303, the receiver counts the number of unreliable bits in the codeword. Specifically, the receiver detects the number of bits of LLR<T in the n-bit codeword. T denotes a reference value of unreliable LDPC bits. The bit having an absolute LLR value less than T is determined as an unreliable bit.

In step 304 it is determined whether the counted number of unreliable bits is less than or equal to λ. If it is determined that the counted number of unreliable bits is greater than λ in step 304, the receiver proceeds to step 306. If it is determined that the counted number of unreliable bits is less than or equal to λ in step 303, the receiver returns to step 300. When the counted number of unreliable bits is less than or equal to λ, a relevant LDPC decoding algorithm of step 300 may be iteratively performed to correct an error in the unreliable bit. Specifically, λ is the minimum value at which decoding will succeed in the codeword.

In step 306, the receiver calculates an average variation of the number of unreliable bits. The average variation of the number of unreliable bits may be determined by Equation (1) below.

$${S}_{M}^{( l )} = \frac{{C}_{T}^{( l - M )} - {C}_{T}^{( l )}}{M} \qquad ( 1 )$$

S_{M}^{(l)} denotes the average variation of the number of the unreliable bits, T denotes a reference LLR value of unreliable bits, the bit having an absolute LLR value less than T is determined as an unreliable bit, C_{T}^{(l)} denotes the number of unreliable bits in the l^{th} iteration step, and the S_{M}^{(l)} is an average variation of unreliable bits through M iterations with respect to the l^{th} iteration step.

In step 308, the receiver determines whether a relation of |S_{M}^{(l)}|≦α is satisfied. If the relation of |S_{M}^{(l)}|≦α is not satisfied in step 308, the receiver returns to step 300 to perform the relevant LDPC decoding algorithm. The receiver returns to step 300 because it is possible to correct an error in the unreliable bit. The value α is the reference value of S_{M}^{(l)} for determining a decoding success/failure.

If the relation of |S_{M}^{(l)}|≦α is satisfied in step 308, the receiver increases the count in step 310.

In step 312, it is determined whether the value counted in step 310 is equal to P. If the value counted in step 310 is equal to P in step 312, the receiver determines a decoding failure in step 314. Specifically, determines that decoding will fail even when performed up to the maximum decoding iteration count, before performing decoding up to the maximum decoding iteration count. The value P is the maximum count satisfying a specific relation between S_{M}^{(l)} and α (e.g., |S_{M}^{(l)}|≦α). When the specific relation is satisfied P times, the receiver determines a decoding failure, and the methodology terminates.

If the value counted in step 310 is not equal to P in step 312, the receiver returns to step 300 to perform iterative decoding.

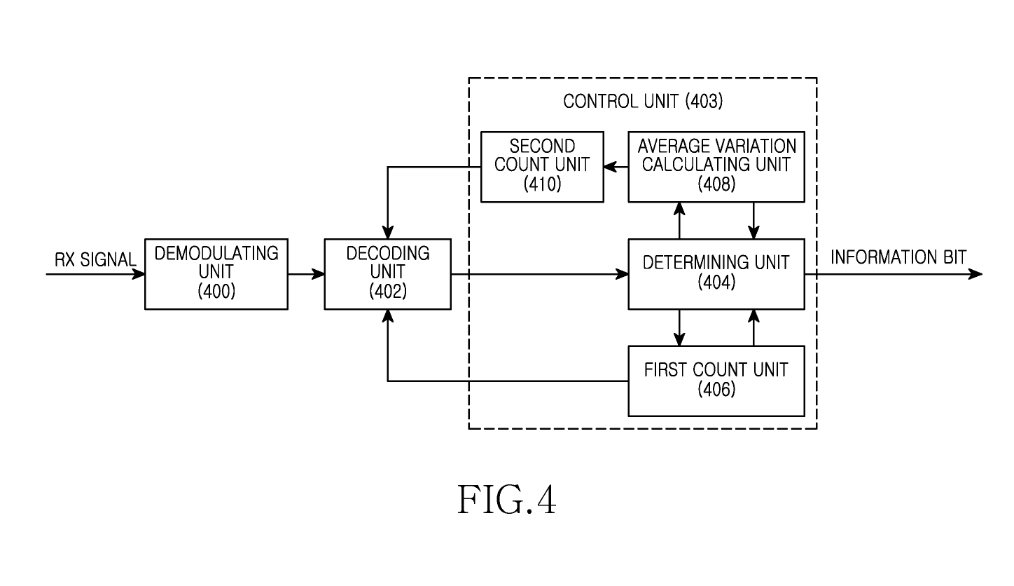

FIG. 4 is a block diagram of an apparatus for controlling LDPC decoding in a receiver, according to an embodiment of the present invention.

Referring to FIG. 4, the receiver includes a demodulating unit 400, a decoding unit 402, a determining unit 404, a first count unit 406, an average variation calculating unit 408, and a second count unit 410. FIG. 4 focuses on an LDPC decoding control apparatus of the receiver. However, in another embodiment of the present invention, the receiver may further include other function blocks in addition to an OFDM/OFDMA modulation block.

A control unit 403 may include the determining unit 404 and the average variation calculating unit 408, and may further include the first count unit 406 and the second count unit 410.

The demodulating unit 400 receives an LDPC code and performs a demodulating operation corresponding to a modulating scheme (e.g., BPSK, QPSK, and 64QAM) of a transmitter. The demodulating unit 400 maps the demodulated signal to LDPC codeword bits and provides the same to the decoding unit 402.

The decoding unit 402 decodes the LDPC codeword bits received from the demodulating unit 400 according to an LDPC decoding algorithm. The LDPC decoding algorithm may be one of a message passing algorithm, a sum product algorithm, and a belief propagation algorithm.

The determining unit 404 performs a syndrome check on the LDPC codeword bits received from the decoding unit 402 and determines whether an equation of H×c=0 is satisfied, where ‘H’ denotes a parity check matrix and ‘c’ denotes a codeword. The determining unit provides the result of H×c=0 to the first count unit 406.

If the equation of H×c=0 is satisfied, it indicates a decoding success and the decoded LDPC codeword bits (i.e., information bits) are outputted. If the equation of H×c=0 is not satisfied, it indicates a decoding failure and the decoding unit 402 perform iterative decoding under the control of the first count unit 406 and the second count unit 410.

The first count unit 406 counts the number of unreliable bits in the LDPC codeword. Specifically, the first count unit 406 detects the number of bits of LLR<T in the n-bit codeword, where T denotes the reference LLR value of unreliable LDPC bits. The bit having an absolute LLR value less than T is determined as an unreliable bit.

When the counted number of unreliable bits is greater than λ, the first count unit 406 notifies this to the determining unit 404. When the counted number of unreliable bits is less than or equal to λ, the first count unit 406 notifies the decoding unit 402.

Specifically, when the counted number of unreliable bits is less than or equal to λ, the first count unit 406 notifies to the decoding unit 402 to iteratively perform an LDPC decoding algorithm to correct an error in the unreliable bit.

When the counted number of unreliable bits is greater than λ, the average variation calculating unit 408 calculates an average variation of the number of unreliable bits on the basis of the information received from the determining unit 404. The average variation of the number of unreliable bits may be determined by Equation (1) above.

The second count unit 410 determines whether the average variation S_{M}^{(l)} of the number of unreliable bits, received from the average variation calculating unit 408, satisfies a relation of |S_{M}^{(l)}|≦α. When the relation of |S_{M}^{(l)}|≦α is not satisfied, the second count unit 410 notifies the decoding unit 402 to iteratively perform an LDPC decoding algorithm. The value α is the reference value of S_{M}^{(l)} for determining a decoding success/failure.

When the relation of |S_{M}^{(l)}|≦α is satisfied, the second count unit 410 increases the count. When the counted value is equal to P, the second count unit 410 determines a decoding failure. The value P is the maximum count satisfying a specific relation between S_{M}^{(l)} and α (e.g., |S_{M}^{(l)}|≦α). When the specific relation is satisfied P times, the receiver determines a decoding failure.

When the counted value is not equal to P, the second count unit 410 notifies the decoding unit 402 to iteratively perform an LDPC decoding algorithm.

As described above, embodiments of the present invention can reduce unnecessary power consumption and latency by determining whether decoding will fail even when performed in a low-SNR region as many times as the maximum decoding iteration count.

While the invention has been shown and described with reference to certain embodiments thereof, it will be understood by those skilled in the art that various changes in form and detail may be made therein without departing from the spirit and scope of the invention as defined by the appended claims. Therefore, the scope of the invention is defined not by the detailed description of the invention but by the appended claims, and all differences within the scope will be construed as being included in embodiments of the present invention.

What is claimed is:

1. A method for controlling decoding in a receiver, comprising the steps of:
receiving and decoding a codeword;
determining whether the decoding is a decoding success or a decoding failure;
determining a number of unreliable bits of the codeword when the decoding is the decoding failure; and
performing iterative decoding when the number of unreliable bits is less than a first threshold value.

2. The method of claim 1, wherein determining whether the decoding is the decoding success or the decoding failure comprises determining whether an equation of H×c=0 is satisfied, where ‘H’ denotes a parity check matrix and ‘c’ denotes the codeword.

3. The method of claim 1, further comprising:
determining an average variation of the number of unreliable bits when the number of unreliable bits is greater than the first threshold value; and
determining the decoding failure of the codeword based on the average variation of the number of unreliable bits.

4. The method of claim 1, wherein the number of unreliable bits is determined based on an absolute Log Likelihood Ratio (LLR) value and a specific reference value.

5. The method of claim 3, wherein determining the decoding failure of the codeword comprises:
increasing a count value when the average variation of the number of unreliable bits is less than or equal to a second threshold value; and
determining the decoding failure of the codeword when the count value is equal to a third threshold value.

6. The method of claim 3, wherein the average variation of the number of unreliable bits is determined by:
$${S}_{M}^{( l )} = \frac{{C}_{T}^{( l - M )} - {C}_{T}^{( l )}}{M}$$
where S_{M}^{(l)} denotes the average variation of the number of unreliable bits, T denotes a reference LLR value of unreliable bits, C_{T}^{(l)} denotes the number of unreliable bits in an l^{th} iteration step, and the S_{M}^{(l)} is the average variation of the number of unreliable bits through M iterations with respect to the l^{th} iteration step.

7. The method of claim 5, wherein the third threshold value comprises a maximum count satisfying |S_{M}^{(l)}|≦α, where S_{M}^{(l)} denotes the average variation of the number of unreliable bits and α denotes the second threshold value.

8. The method of claim 1, wherein the codeword is Low Density Parity Check (LDPC)-encoded.

9. A receiver comprising:
a decoding unit for decoding a received codeword; and
a control unit for determining whether the decoding is a decoding success or decoding failure, determining a number of unreliable bits of the codeword when the decoding is the decoding failure, and performing iterative decoding when the number of unreliable bits is less than a first threshold value.

10. The receiver of claim 9, wherein the control unit comprises a determining unit for determining whether H×c=0 is satisfied, where ‘H’ denotes a parity check matrix and ‘c’ denotes the codeword.

11. The receiver of claim 9, wherein the control unit comprises:
a first count unit for determining the number of unreliable bits;
an average variation calculating unit for determining an average variation of the number of unreliable bits when the number of unreliable bits is greater than the first threshold value; and
a second count unit for determining a decoding failure based on the average variation of the number of unreliable bits.

12. The receiver of claim 9, wherein the number of unreliable bits is determined based on an absolute Log Likelihood Ratio (LLR) value and a specific reference value.

13. The receiver of claim 11, wherein the second count unit:
increases a count value when the average variation of the number of unreliable bits is less than or equal to a second threshold value; and
determines the decoding failure of the codeword when the count value is equal to a third threshold value.

14. The receiver of claim 11, wherein the average variation of the number of unreliable bits is determined by:
$${S}_{M}^{( l )} = \frac{{C}_{T}^{( l - M )} - {C}_{T}^{( l )}}{M}$$
where S_{M}^{(l)} denotes the average variation of the number of unreliable bits, T denotes a reference LLR value of unreliable bits, C_{T}^{(l)} denotes the number of unreliable bits in an l^{th} iteration step, and the S_{M}^{(l)} is the average variation of the number of unreliable bits through M iterations with respect to the l^{th} iteration step.

15. The receiver of claim 13, wherein the third threshold value is determined as a maximum count satisfying |S_{M}^{(l)}|≦α, where S_{M}^{(l)} denotes the average variation of the number of unreliable bits and α denotes the second threshold value.

16. A method for controlling decoding in a receiver, comprising the steps of:
decoding a codeword;
determining a number of unreliable bits of the codeword when the decoding of the codeword is a decoding failure, and determining an average variation of the number of unreliable bits;
determining a number of times when the average variation of the number of unreliable bits decreases below a first threshold value during iterative decoding; and
terminating the iterative decoding when the determined number of times reaches a second threshold value.

17. The method of claim 16, wherein the number of unreliable bits is determined based on an absolute Log Likelihood Ratio (LLR) value.

18. The method of claim 16, wherein the iterative decoding continues when the number of unreliable bits is less than a third threshold value.

19. The method of claim 16, wherein the iterative decoding continues when the determined number of times does not reach the second threshold value.

20. The method of claim 16, wherein the codeword is Low Density Parity Check (LDPC)-encoded.
